(19) United States
(12) Patent Application Publication
(10) Pub. No.: US 2010/0133631 A1
(43) Pub. Date: Jun. 3, 2010

(54) DIFFERENTIAL-PRESSURE SENSOR SYSTEM AND CORRESPONDING PRODUCTION METHOD

(76) Inventor: Hubert BENZEL, Pliezhausen (DE)

Correspondence Address: KENYON & KENYON LLP, ONE BROADWAY, NEW YORK, NY, 10004, US

(21) Appl. No.: 12/598,261

(22) PCT Filed: Mar. 19, 2008
(86) PCT No.: PCT/EP2008/053318

§ 371 Date: Oct. 30, 2009

(30) Foreign Application Priority Data
May 15, 2007 (DE) 102007022852.1

(51) Int. Cl. H01L 29/84; B29C 45/14

(52) U.S. Cl. 257/417; 264/279; 257/E29.324

(57) ABSTRACT

A differential-pressure sensor system and a corresponding production method. The differential-pressure sensor system includes: a differential-pressure sensor chip having a first pressure application region for applying a first pressure, as pressure to be detected, to the differential-pressure sensor chip, and a second pressure application region for applying a second pressure, as reference pressure, to the differential-pressure sensor chip; a housing that partially surrounds the differential-pressure sensor chip; the housing having a through hole, through which the first pressure application region is exposed to the outside; and the housing having an input opening, through which the second pressure application region is exposed to the outside.

### FIELD OF THE INVENTION

The present invention relates to a differential-pressure sensor system and a corresponding production method.

Although applicable to any semiconductor chip system, the present invention as well as the problem underlying it are explained with respect to a micromechanical silicon semiconductor chip system having an integrated differential-pressure sensor.

### BACKGROUND INFORMATION

German Patent Application No. DE 10 2004 051 468 A1 describes a method for mounting semiconductor chips, which has the following steps:
providing a semiconductor chip having a surface that has a diaphragm region and a peripheral region, the peripheral region having a mounting region, and a cavity being situated underneath the diaphragm region, which cavity extends into the mounting region and ends there in an opening;
providing a substrate that has a surface having a cut-out;
mounting the mounting region of the semiconductor chip in flip-chip technology on the surface of the substrate such that an edge of the cut-out is situated between the mounting region and the diaphragm region, and the opening is directed toward the substrate;
underfilling the mounting region using an underfilling, the edge of the cut-out acting as a separating region for the underfilling, so that no underfilling reaches the diaphragm region; and
providing a through-hole through the substrate to the opening of the cavity.

German Patent Application No. DE 10 2005 038 443 A1 describes a sensor system having a substrate and having a housing, the housing generally completely surrounding the substrate in a first substrate region, and the housing being at least partially provided with an opening in a second substrate region. The second substrate region is provided in a manner projecting out of the housing in the region of the opening. Furthermore, it may be gathered from this printed publication that the housing at least partially surrounds the second substrate region at least with clearance in a main plane of the substrate, so that a through-hole is formed in this manner, into which the second substrate region projects on one side.

In general, today micromechanical silicon pressure sensors having piezoresistive transformer elements are widespread. To produce a diaphragm, a cavity is introduced into a silicon chip by anisotropic etching, for example. In this context, a glass plate that is bonded in an anodic manner to the back side of the wafer serves to reduce the mechanical stress that is generated by solder or adhesive agents. The sensor chip is normally soldered into a metallic housing, e.g., TO₈, and welded to a metal cap in a hermetically sealed manner. An alternative mounting method is to adhere the sensor chip onto a ceramic or into a premolded housing, and to passivate it using a gel to protect against environmental influences.

The production of an absolute pressure sensor chip is described in International Patent Application WO 02/02458 A1, the diaphragm being produced through porous silicon that is produced in the region of the diaphragm before an epitaxy layer and that rearranges during the epitaxy such that a cavity forms.

### SUMMARY

In accordance with the present invention, a differential-pressure sensor chip is provided having a projecting sensor region in open-cavity mold technology, and a second pressure connection for applying the reference pressure in the housing. The differential-pressure sensor system according to the present invention is resistant to media and is also suitable for particle-containing and etching media.

In contrast to the conventional design approaches, the differential-pressure sensor system according to the present invention and the corresponding production method may have the advantage that they allow for a construction that is simple, cost-effective, and insensitive to environmental influence. There are advantages with regard to low packaging costs during molding-in. Compared to an absolute pressure sensor without a second pressure connection, except for an additional silicon separation step to open a second pressure access opening, no further process steps are required.

The etching step for opening the second pressure access opening does not have to be performed through the entire wafer, but rather only through the thickness of the diaphragm. This saves process time. The potential clogging of the connection channel from the diaphragm cavity to the second pressure access opening by particles in the medium may be prevented by a large-area, fine-grid filter sieve or mesh.

The example construction according to the present invention is resistant to media, since the electric connections (typically made of aluminum) are protected by molding substances. Only surfaces made of silicon or silicon nitride (passivation) may be reached by the pressure medium. Silicon or silicon nitride, and thus the entire sensor, is particularly resistant to media. A gel for passivating the electrical chip connections (bond pads) is not necessary. One particular advantage is therefore a very low cross sensitivity to acceleration, and usability at higher pressures. In sensors protected by gel, the structure of the gel would be destroyed in the event of sudden drops in pressure, by small gas bubbles that form in the gel in the process (similar to aeroembolism). A monocrystalline silicon diaphragm may be produced. One particular advantage of it is the high mechanical strength or the high K factor of piezo-resistors that are doped in it. Existing processes for producing pressure sensors may be retained, for the most part. The projecting chip allows for a good stress buffer from the sensor diaphragm. Mechanical stress is broken down through the spatial separation of the mounting region from the diaphragm region. The electric initial testing in the wafer composite is possible, and a band adjustment is possible after the mounting. The geometry of the diaphragm region may be configured as desired, but preferably has a square, rectangular or round design.

### BRIEF DESCRIPTION OF THE DRAWINGS

Exemplary embodiments of the present invention are shown in the figures and are explained in greater detail below.

FIG. 1a, b show schematic sectional views of a part of the process for producing a micromechanical silicon semiconductor chip system having an integrated differential-pressure sensor, which may be used in the differential-pressure sensor system according to the present invention.

FIG. 2a, b show schematic sectional views of a first specific embodiment of the differential-pressure sensor system according to the present invention.

FIG. 3 shows a schematic sectional view of a second specific embodiment of the differential-pressure sensor system according to the present invention.

FIG. 4 shows a schematic sectional view of a third specific embodiment of the differential-pressure sensor system according to the present invention.

FIG. 5 shows a schematic sectional view of a fourth specific embodiment of the differential-pressure sensor system according to the present invention.

FIG. 6 shows a schematic sectional view of a fifth specific embodiment of the differential-pressure sensor system according to the present invention.

### DETAILED DESCRIPTION OF EXAMPLE EMBODIMENTS

In the figures, like reference numerals designate like or functionally equivalent components.

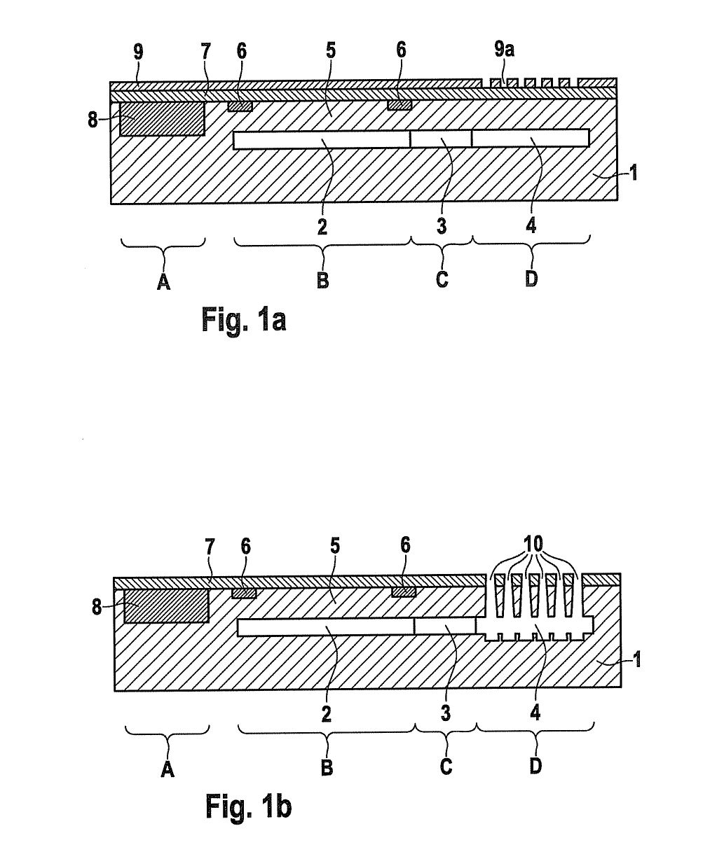

FIGS. 1a, b show schematic sectional views of a part of the process for producing a micromechanical silicon semiconductor chip system having an integrated differential-pressure sensor, which may be used in the differential-pressure sensor system according to the present invention.

In FIGS. 1a, b reference numeral 1 labels a silicon semiconductor chip having an evaluation circuit region A, a measuring pressure access region or application region B, a connection channel region C, and a reference pressure access region or application region D.

A diaphragm 5, under which a diaphragm cavity 2, a connection channel 3, and a reference pressure access space 4 have been produced, are produced in accordance with a method described in International Patent Application No. WO 02/02458 A1, for example. Piezoresistive resistors 6 are provided on the upper side of diaphragm 5, whose electrical behavior is used to detect the applied measuring pressure when diaphragm 5 is distorted, a corresponding counterpressure being produced by the reference pressure. Reference numeral 8 labels an optional integrated evaluation circuit. A chip passivation 7, of silicon nitride, for example, is provided above the diaphragm.

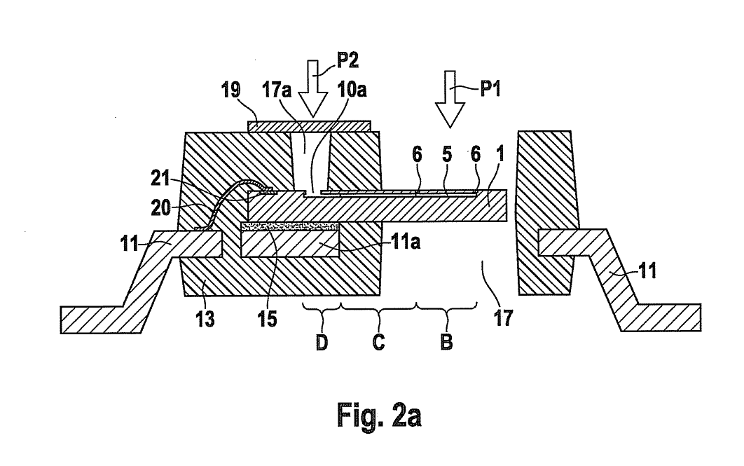

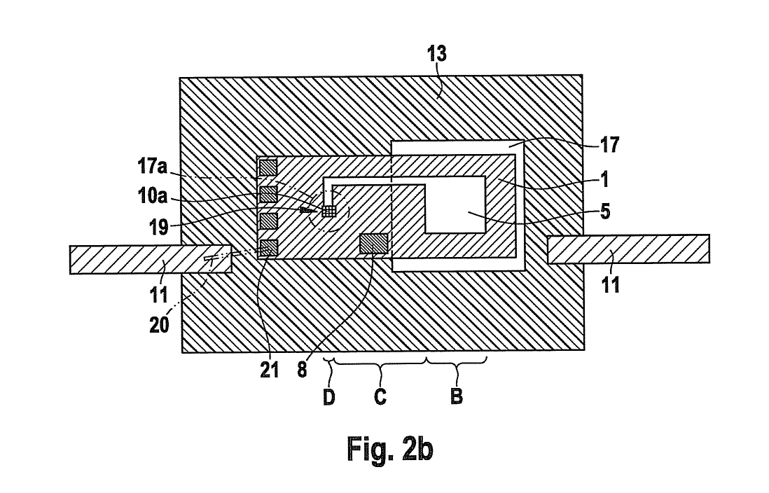

To produce a second pressure access opening, a photo mask 9 having mask openings 9a is provided above chip passivation layer 7. Subsequently, a trench-etching step is performed to form one (reference numeral 10a in FIGS. 2 through 6) or more through holes 10 (for example, lattice-shaped) that allow for an external reference pressure to be applied to reference pressure access space 4.

The functioning method of such a differential-pressure sensor chip 1 thus comprises applying a pressure to be measured in the region of diaphragm 5 having piezoresistive resistors 6, and at the same time applying a reference pressure in the region of the opening(s) 10a and 10, respectively. To prevent stress from the connection channel from possibly interfering with piezoresistive elements 6, it is advantageous to provide connection channel 3 at a suitable distance from piezoresistive elements 6 (cf. FIG. 2b). If diaphragm 5 is not completely removed in the region of second pressure connection region 4, but rather a lattice is produced, it is possible to prevent the intrusion of particles. If very many, very small access openings are inserted over a large surface in this lattice, an obstruction of the lattice may also be attenuated, in a manner similar to that in a gel passivation.

FIGS. 2a, b show schematic sectional views of a first specific embodiment of the differential-pressure sensor system according to the present invention.

In accordance with FIG. 2a, the mounting of sensor chip 1 is performed by providing an adhesive layer 15 on a mounting region 11a of a lead frame having connection regions 11 and mounting region 11a. Subsequently, a bond wire 20 is used to produce an electric connection between a bond pad 21 of the differential-pressure sensor chip 1 and a connection region 11 of the lead frame. Afterwards, differential-pressure sensor chip 1 is extrusion coated using an injection-molding substance or molding substance, a through hole 17 in the measuring pressure access region B and an input opening 17a in the reference pressure access region D being kept free by appropriate plungers or placeholders. After the extrusion coating and hardening of the molding substance, a particle filter 19 is expediently provided on the housing above input opening 17a, by cementing, for example, to protect second pressure connection 10a.

As shown in FIG. 2b, connection channel region C proceeds to the edge of measuring pressure access region B, in order to achieve a suitable stress buffer. Reference numeral P1 in FIG. 2a labels the pressure to be applied, which is to be measured, whereas reference numeral P2 labels the reference pressure to be applied in region D.

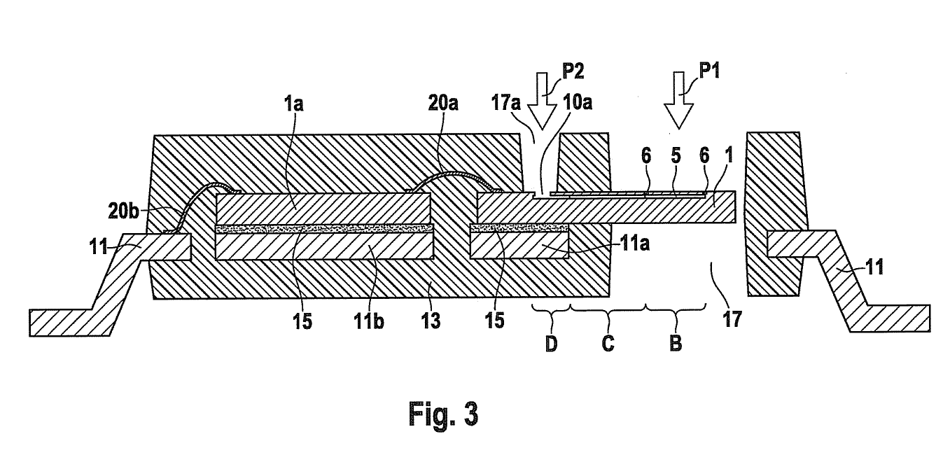

FIG. 3 shows a schematic sectional view of a second specific embodiment of the differential-pressure sensor system according to the present invention.

In the second specific embodiment in accordance with FIG. 3, an evaluation circuit is provided in a separate evaluation chip 1a, which is provided using adhesive layer 15 in an additional mounting region 11b of the lead frame. Evaluation chip 1a is connected to differential-pressure sensor chip 1 by a first bond connection 20a and to a connection region 11 of the lead frame by a second bond wire 20b.

Evaluation chip 1a is cemented onto the lead frame along with differential-pressure sensor chip 1; however, in contrast to differential-pressure sensor chip 1, it is completely surrounded by the molding substance of housing 13.

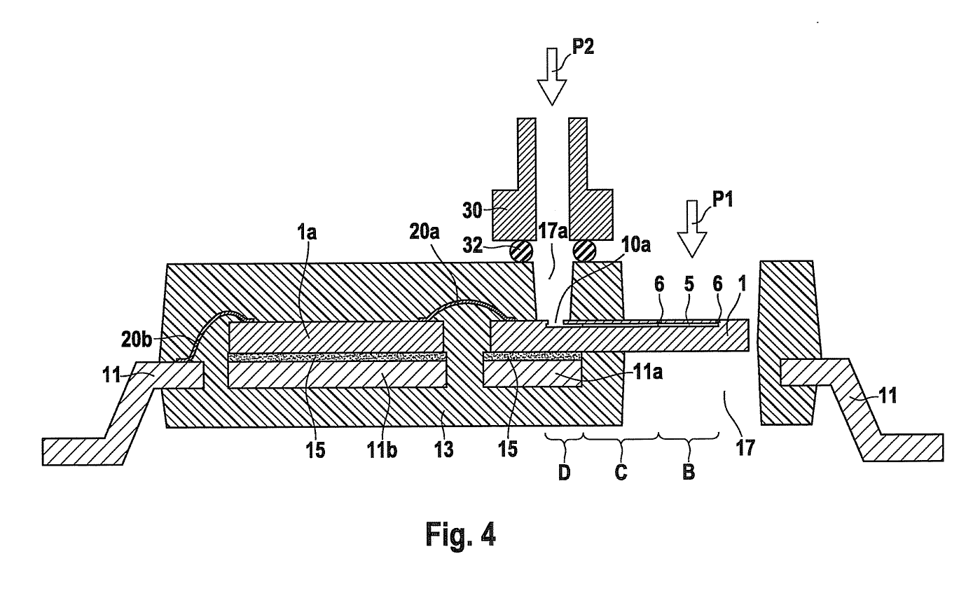

FIG. 4 shows a schematic sectional view of a third specific embodiment of the differential-pressure sensor system according to the present invention.

In the third specific embodiment according to FIG. 4, further to the second specific embodiment according to FIG. 3, a pressure connection piece 30 is sealed on by an O-ring 32 above input opening 17a. Alternatively, pressure connection piece 30 could also be cemented on or soldered on.

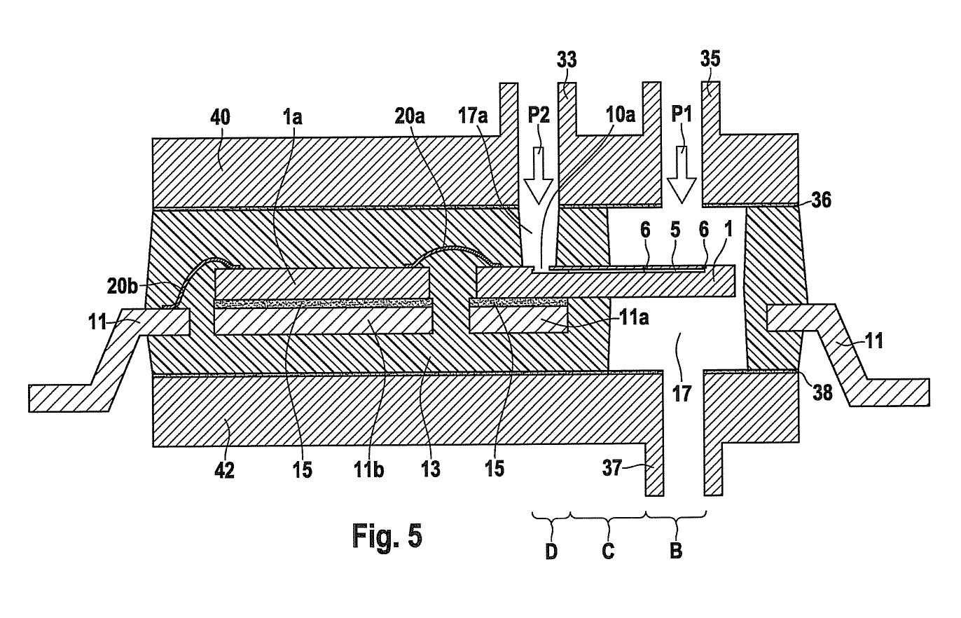

FIG. 5 shows a schematic sectional view of a fourth specific embodiment of the differential-pressure sensor system according to the present invention.

In the fourth specific embodiment according to FIG. 5, a first and second pressure connection plate 40 and 42, respectively, are provided above and below housing 13 and are sealingly connected thereto via a respective plastic seal 36, 38 having corresponding openings. Pressure connection pieces 33, 35 are integrated into first pressure connection plate 40 in accordance with pressure accesses to through hole 17 and input opening 17a, respectively.

Second pressure connection plate 42 has an integrated pressure connection piece 37 in accordance with the pressure outlet of through hole 17. Clearly, the pressure connection of pressure P1 to be measured may also take place at the underside. A possible screw fitting or clamping for the sealing connection of pressure connection plates 40, 42 to housing 13 are not shown.

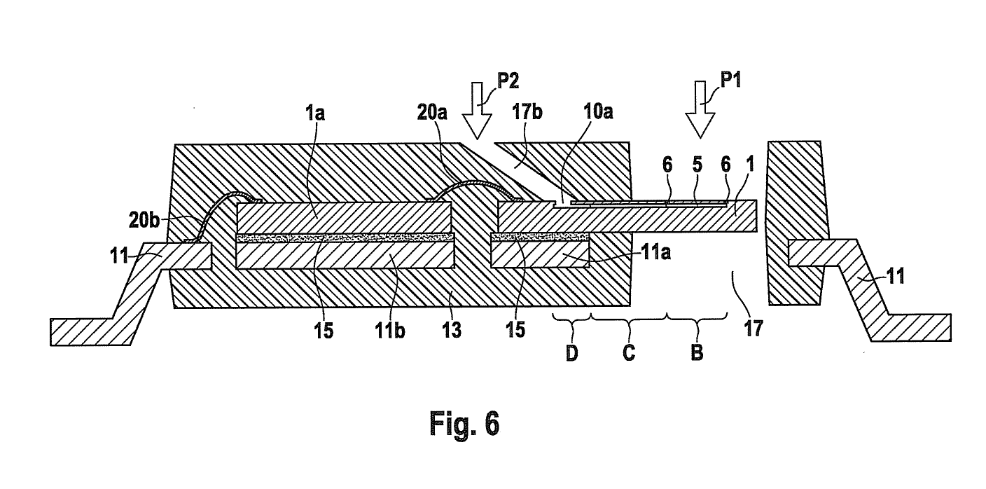

FIG. 6 shows a schematic sectional view of a fifth specific embodiment of the differential-pressure sensor system according to the present invention.

In the fifth specific embodiment shown in FIG. 6, input opening 17b for applying reference pressure P2 is formed at an angle in housing 13. In other words, in housing 13, it extends at an angle, with regard to a perpendicular to the chip surface of differential-pressure sensor chip 1 in the second pressure application region D. Such an arrangement makes it possible to enlarge the distance for the sealing between the first and second pressure access. This simplifies the sealing of the two pressure accesses at the pressure connection pieces or separate pressure lines, for example.

Although the present invention has been explained above with reference to preferred exemplary embodiments, it is not restricted to them, but may be implemented in other ways as well.

Only piezoresistive sensor structures were considered in the above examples. However, the present invention is also suitable for capacitive or other sensor structures, in which differential-pressure measuring diaphragms are used.

1-13. (canceled)

14. A differential-pressure sensor system, comprising:
a differential-pressure sensor chip, which has a first pressure application region for applying a first pressure to the differential-pressure sensor chip as pressure to be detected, and a second pressure application region for applying a second pressure to the differential-pressure sensor chip as reference pressure, the first and the second pressure application region being connected by a connection channel region; and
a housing which partially surrounds the differential-pressure sensor chip, the housing having a through hole, through which the first pressure application region is exposed to the outside, and an input opening through which the second pressure application region is exposed to the outside.

15. The differential-pressure sensor system as recited in claim 14, wherein at an edge, the connection channel ends in an opening into the first pressure application region.

16. The differential-pressure sensor system as recited in claim 14, wherein the second pressure application region has a lattice.

17. The differential-pressure sensor system as recited in claim 14, the first pressure application region projecting into the through hole on one side.

18. The differential-pressure sensor system as recited in claim 14, wherein the housing is formed from an injection-molding substance.

19. The differential-pressure sensor system as recited in claim 14, further comprising:
a filter mounted on the housing above the input opening.

20. The differential-pressure sensor system as recited in claim 14, further comprising:
an evaluation chip electrically connected to the differential-pressure sensor chip, the evaluation chip being at least partially surrounded by the housing.

21. The differential-pressure sensor system as recited in claim 14, further comprising:
a lead frame, the differential-pressure sensor chip being mounted on the lead frame.

22. The differential-pressure sensor system as recited in claim 14, further comprising:
a pressure connection piece sealingly mounted on the housing above the input opening.

23. The differential-pressure sensor system as recited in claim 14, further comprising:
a first pressure connection plate having a corresponding first and second integrated pressure connection piece sealingly mounted on the housing above the input opening and above the through hole.

24. The differential-pressure sensor system as recited in claim 14, further comprising:
a second pressure connection plate having a corresponding third integrated pressure connection piece sealingly mounted on the housing beneath the through hole.

25. The differential-pressure sensor system as recited in claim 14, wherein the input opening has an extension in the housing that is oriented at an angle with regard to a perpendicular to a chip surface in the second pressure application region.

26. A method for producing a differential-pressure sensor system, comprising:
producing a housing by injection molding a differential-pressure sensor chip using an injection-molding substance, the pressure differential chip having a first pressure application region for applying a first pressure to the differential-pressure sensor chip as pressure to be detected, and a second pressure application region for applying a second pressure to the differential-pressure sensor chip as reference pressure, the first and second pressure application region being connected to a connection channel region, the housing partially surrounding the differential-pressure sensor chip and having a through hole through which the first pressure application region is exposed to the outside, and an input opening through which the second pressure application region is exposed to the outside, the input opening and the through hole being formed by corresponding place holders during extrusion coating.
